(19) United States
(12) Patent Application Publication
(10) Pub. No.: US 2008/0268343 A1
(43) Pub. Date: Oct. 30, 2008

(54) ELECTROCHEMICAL ELEMENT AND ELECTRODE THEREOF, METHOD AND APPARATUS FOR MANUFACTURING THE ELECTRODE, METHOD AND APPARATUS FOR LITHIATION TREATMENT

(76) Inventors: Toshitada Sato, Osaka (JP); Kazuyoshi Honda, Osaka (JP); Shinya Fujimura, Osaka (JP)

Correspondence Address: MCDERMOTT WILL & EMERY LLP, 600 13TH STREET, NW, WASHINGTON, DC, 20005-3096, US

(21) Appl. No.: 12/058,186

(22) Filed: Mar. 28, 2008

(30) Foreign Application Priority Data
Apr. 27, 2007 (JP) 2007-118682

(51) Int. Cl. H01M 4/26; C23C 16/06; H01M 4/36

(52) U.S. Cl. 429/231.95; 427/124; 118/715; 118/712; 118/724; 429/225

(57) ABSTRACT

A method for manufacturing an electrode of an electrochemical element includes providing lithium and an element that has a larger atomic weight than that of lithium and is other than a constituting material of the electrode to an electrode by using a lithium vapor and a vapor of the element.

### BACKGROUND OF THE INVENTION

1. Field of the Invention

The present invention relates to a manufacturing method including treatment for providing lithium to an active material layer of an electrode for an electrochemical element and a manufacturing apparatus including a lithiation treatment apparatus, as well as an electrode manufactured by using the same and an electrochemical element using the same. More particularly, it relates to a treatment method for providing lithium to a negative electrode for a non-aqueous electrolyte secondary battery and a manufacturing method including the same, a manufacturing apparatus including a lithiation treatment apparatus, a negative electrode manufactured by using the same, and a non-aqueous electrolyte secondary battery using the same.

2. Background Art

Recently, with the widespread use of portable and cordless electronic equipment, the expectation has been also increasing for compact, lightweight secondary batteries with large energy density as a driving power source for such equipment. Furthermore, technology development of not only batteries used for small consumer goods but also large secondary batteries for electric power storages and electric vehicles, which require a long-time durability and safety, has been accelerated. From such a viewpoint, a non-aqueous electrolyte secondary battery having high voltage and large energy density, in particular, a lithium secondary battery is expected as a power source for electronic equipment, electric power storage or an electric vehicle.

A non-aqueous electrolyte secondary battery includes a positive electrode, a negative electrode, a separator interposed therebetween and a non-aqueous electrolyte. A separator is mainly composed of a microporous polyolefin film. As a non-aqueous electrolyte, a liquid-state non-aqueous electrolyte (non-aqueous electrolyte solution) obtained by dissolving a lithium salt such as LiBF₄ and LiPF₆ in an aprotic organic solvent is used. As an active material for the positive electrode, lithium cobalt oxide (for example, LiCoO₂) is used. Lithium cobalt oxide has a high electric potential with respect to lithium, is excellent in safety and is synthesized relatively easily. As an active material for the negative electrode, various carbon materials such as graphite are used. Non-aqueous electrolyte secondary batteries having such a configuration are made into practical use.

Since graphite used as an active material for a negative electrode can absorb one lithium atom per six carbon atoms theoretically, a theoretical capacity density of graphite is 372 mAh/g. However, by a capacity loss due to the irreversible capacity, the actual capacity density is reduced to about 310 to 330 mAh/g. Therefore, it is basically difficult to obtain a carbon material capable of absorbing and releasing lithium ions at this capacity density or more.

Then, in the circumstances where batteries with a larger energy density are demanded, silicon (Si), tin (Sn), germanium (Ge) and oxides or alloys thereof have been expected as a negative electrode active material having a large theoretical capacity density. Among them, Si and oxide of Si have been widely studied because they are inexpensive.

However, when Si, Sn, Ge, oxides thereof and alloys thereof absorb lithium ions, the crystalline structure thereof is changed and the volume thereof is increased. When the active material largely expands at the time of charging, the contact failure between the active material and a current collector occurs. Consequently, the charge and discharge cycle lifetime becomes shorter. In order to address such a problem, the following proposals have been made.

For example, from the viewpoint of addressing a problem of the contact failure between the active material and the current collector due to expansion, a method for forming a thin film of an active material on the surface of a current collector has been proposed (for example, see Japanese Patent Application Unexamined Publication No. 2002-83594). Furthermore, a method for forming an active material in a columnar shape and in an inclined state on the surface of a current collector has been proposed (see, for example, Japanese Patent Application Unexamined Publication No. 2005-196970). According to these proposals, by strongly metallic bonding an active material and a current collector to each other, stable current collection can be secured. In particular, in a latter case, space that is necessary and sufficient to absorb expansion is secured around the columnar active material. Therefore, collapse of the negative electrode itself due to the expansion and contraction of the active material is prevented, and press-stress to the separator and the positive electrode is reduced, and thereby, the charge and discharge cycle characteristic can be specifically improved.

However, when silicon oxide (SiOₓ (0≦x≦2)) is used as the active material, an irreversible capacity generated at the initial charge is very large. Therefore, when such a negative electrode is used as it is in combination with the positive electrode, a large portion of the reversible capacity of the positive electrode is used as the irreversible capacity. Therefore, in order to realize a battery with large capacity by using silicon oxide as an active material for a negative electrode, it is necessary to compensate lithium from other than positive electrode.

Therefore, as a way for compensating lithium ions, a large number of ways of providing metallic lithium onto the negative electrode and allowing it to be absorbed by a solid phase reaction have been proposed. For example, a process of vapor-depositing lithium on the surface of the negative electrode, and a process of storing the negative electrode have been proposed (for example, Japanese Patent Application Unexamined Publication No. 2005-38720).

An active material can be formed by the methods described in Japanese Patent Application Unexamined Publication Nos. 2002-83594 and 2005-196970 and lithium can be vapor deposited on the surface of the negative electrode as described in Japanese Patent Application Unexamined Publication No. 2005-38720. In this case, the deposition amount of lithium can be determined as follows. For example, a smooth current collector is used instead of a negative electrode, lithium is actually vapor-deposited, and the deposition amount is determined. However, in this method, when the generation amount of a lithium vapor is changed, this change cannot be detected, and the deposition amount of lithium varies. In order to address such a problem, determination can be carried out when the film thickness before and after lithium vapor deposition treatment is measured by a laser displacement gauge or a contact displacement gauge in the apparatus. However, since lithium after vapor deposition is absorbed by an active material layer for a short time, it is necessary to set a displacement gauge right behind a vapor deposition portion. Thus, the degree of freedom of setting in the apparatus is limited, and the measurement accuracy is deteriorated due to a variation in absorption.

### SUMMARY OF THE INVENTION

The present invention relates to a method for manufacturing an electrode for an electrochemical element having a large capacity by grasping and stabilizing an amount of provided lithium. The method for manufacturing an electrode for an electrochemical element in accordance with the present invention includes providing lithium and an element that has a larger atomic weight than that of lithium and is other than a material constituting the electrode to an electrode by using a lithium vapor and a vapor of the element. In this way, by providing the element that has a larger atomic weight than that of lithium and is other than a constituting material of the electrode together with lithium, it is possible to estimate an amount of lithium provided per unit area of the electrode. Thus, it is possible to manage the amount of provided lithium. Therefore, it is possible to provide an electrochemical element having a large capacity, which reliably compensates the irreversible capacity attributed to the electrode.

### BRIEF DESCRIPTION OF THE DRAWINGS

FIG. 1 is a longitudinal sectional view showing a non-aqueous electrolyte secondary battery in accordance with an embodiment of the present invention.

FIG. 2 is a schematic configuration view showing an active material layer-formation section of an apparatus for manufacturing a negative electrode for a non-aqueous electrolyte secondary battery in accordance with an embodiment of the present invention.

FIG. 3 is a schematic configuration view showing a lithium providing section of the apparatus for manufacturing a negative electrode for a non-aqueous electrolyte secondary battery in accordance with an embodiment of the present invention.

FIG. 4 is an enlarged sectional view showing a principal part of the lithium providing section shown in FIG. 3.

FIG. 5 is a view showing a configuration of a periphery of a fluorescent X-ray analyzer as a measurement section incorporated in the lithium providing section shown in FIG. 3.

FIG. 6 is an enlarged view of a principal part showing another configuration of the lithium providing section shown in FIG. 3.

FIG. 7 is a schematic configuration view showing another active material layer-formation section of an apparatus for manufacturing a negative electrode for a non-aqueous electrolyte secondary battery in accordance with the embodiment of the present invention.

FIG. 8 is a sectional view showing a negative electrode for a non-aqueous electrolyte secondary battery produced by using the active material layer-formation section shown in FIG. 7.

FIG. 9 is a schematic configuration view showing a further active material layer-formation section of an apparatus for manufacturing a negative electrode for a non-aqueous electrolyte secondary battery in accordance with the embodiment of the present invention.

FIG. 10 is a sectional view showing a negative electrode for a non-aqueous electrolyte secondary battery manufactured by using the active material layer-formation section shown in FIG. 9.

### DETAILED DESCRIPTION OF THE INVENTION

Hereinafter, the embodiments of the present invention are described with reference to drawings in which a non-aqueous electrolyte secondary battery is employed as an example of an electrochemical element, and a negative electrode is employed as an example of an electrode. Note here that the present invention is not limited to contents described below as long as it is based on basic features described in this specification.

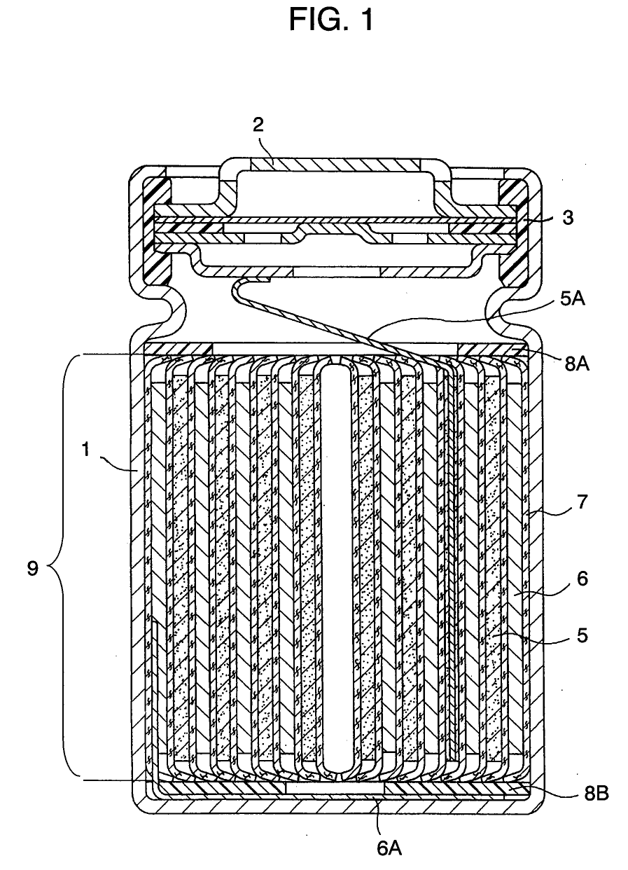

FIG. 1 is a longitudinal sectional view showing a non-aqueous electrolyte secondary battery in accordance with an embodiment of the present invention. Herein, a cylindrical battery is described as an example. This non-aqueous electrolyte secondary battery includes metallic case 1 and electrode group 9 accommodated in case 1. Case 1 is made of stainless steel or nickel-plated iron. Electrode group 9 is produced by winding negative electrode 6 as a first electrode and positive electrode 5 as a second electrode via separator 7 in a spiral shape. Upper insulating plate 8A is disposed at the top of electrode group 9, and lower insulating plate 8B is disposed at the bottom of electrode group 9. An open end of case 1 is sealed with sealing plate 2 via gasket 3 by caulking case 1 with respect to sealing plate 2. One end of positive electrode lead 5A made of aluminum is attached to positive electrode 5. Another end of positive electrode lead 5A is coupled to sealing plate 2 that also serves as a positive terminal. One end of negative electrode lead 6A made of nickel is attached to negative electrode 6. Another end of negative electrode lead 6A is coupled to case 1 that also serves as a negative electrode terminal. Electrode group 9 is impregnated with a non-aqueous electrolyte (not shown) serving as an electrolyte. That is to say, a non-aqueous electrolyte is interposed between positive electrode 5 and negative electrode 6.

In general, positive electrode 5 includes a positive current collector and a positive electrode mixture supported thereby. The positive electrode mixture can include a binder, a conductive agent, and the like, in addition to a positive electrode active material. Positive electrode 5 is produced by, for example, preparing a positive electrode mixture slurry by mixing a positive electrode mixture composed of a positive electrode active material and an arbitrary component with a liquid component, and then coating and drying the obtained slurry on a positive current collector.

As the positive electrode active material of the non-aqueous electrolyte secondary battery, complex oxide of lithium and other metal can be used. An example thereof includes LiₓCoO₂, LiₓNiO₂, LiₓMnO₂, LiₓCo_{y}M_{1-y}O_{z}, LiₓNi_{1-y}M_{y}O_{z}, LiₓMn₂O₄, LiₓMn_{2-z}M_{z}O₄, LiMPO₄, and Li₂ MPO₄F. Herein, M denotes at least one selected from Na, Mg, Sc, Y, Mn, Fe, Co, Ni, Cu, Zn, Al, Cr, Pb, Sb and B, and 0≦x≦1.2, 0≦y≦0.9 and 0≦z≦1.9 are satisfied. Note here that the value x showing the molar ratio of lithium represents a value right after the active material is produced, and the value is increased and decreased by charge and discharge. Furthermore, a part of these lithium-containing compounds may be substituted by a different kind of element. The surface of the positive electrode active material may be treated with metallic oxide, lithium oxide, a conductive agent, and the like, and the surface may be subjected to hydrophobic treatment.

An example of the binder of the positive electrode mixture may include polyvinylidene-fluoride (PVDF), polytetrafluoroethylene, polyethylene, polypropylene, aramid resin, polyamide, polyimide, polyamide-imide, polyacrylonitrile, polyacrylic acid, polymethylacrylate, polyethylacrylate, polyhexylacrylate, polymethacrylic acid, polymethylmethacrylate, polyethylmethacrylate, polyhexylmethacrylate, polyvinyl acetate, polyvinylpyrrolidone, polyether, polyethersulfone, hexafluoropolypropylene, styrene-butadiene rubber, carboxymethylcellulose, and the like. Furthermore, a copolymer of two or more kinds of materials selected from tetrafluoroethylene, hexafluoroethylene, hexafluoropropylene, perfluoro-alkylvinyl ether, vinylidenefluoride, chlorotrifluoroethylene, ethylene, propylene, pentafluoropropylene, fluoromethylvinyl ether, acrylic acid, and hexadiene, may be used singly or in a combination of two or more thereof.

An example of the conductive agent may include graphites including natural graphites and artificial graphites; carbon blacks such as acetylene black, Ketjen black, channel black, furnace black, lampblack and thermal black; conductive fibers such as carbon fiber and metal fiber; metal powders such as aluminum powder; whiskers of conducive compounds such as zinc oxide, potassium titanate, and the like; conductive metal oxide such as titanium oxide; an organic conductive material such as phenylene derivatives, and the like.

It is preferable that the blending percentages of the positive electrode active material, conductive agent and binder are 80 to 97 wt. %, 1 to 20 wt. %, and 2 to 7 wt. %, respectively.

As the positive current collector, a long porous conductive plate or a non-porous conductive plate is used. An example of materials to be used for the conductive plate may include stainless steel, aluminum, titanium, and the like. The thickness of the current collector is not particularly limited. However, the thickness is preferably in the range from 1 to 500 μm, and more preferably in the range from 5 to 20 μm. When the thickness of the current collector is in the above-mentioned range, the weight of the electrode can be reduced while the electrode keeps an adequate strength.

For separator 7, microporous thin film, woven fabric, non-woven fabric, and the like, having a high ionic permeability and also having a predetermined mechanical strength and insulating property are used. As materials for separator 7, for example, polyolefin such as polypropylene and polyethylene is preferable from the viewpoint of safety of a non-aqueous electrolyte secondary battery because it is excellent in durability and has a shutdown function. The thickness of separator 7 is generally in the range of 10 to 300 μm and desirably 40 μm or less. More preferably, it is in the range of 5 to 30 μm, and further preferably in the range of 10 to 25 μm. Furthermore, the microporous film may be a single layer film consisting of one kind of material or may be a composite film or a multi-layer film consisting of two or more kinds of materials. Furthermore, it is preferable that the porosity of separator 7 is in the range of 30 to 70%. Herein, the porosity means the area ratio of pores occupying the surface area of separator 7. The more preferable porosity of separator 7 is in the range of 35 to 60%.

As the non-aqueous electrolyte, liquid state, gel state, and solid state (polymer solid electrolyte) materials can be used. The liquid state non-aqueous electrolyte (non-aqueous electrolyte solution) can be prepared by dissolving an electrolyte (for example, lithium salt) in a non-aqueous solvent. The gel state non-aqueous electrolyte is composed of a liquid-state non-aqueous electrolyte and a polymer material holding the liquid state non-aqueous electrolyte. As the polymer material, for example, PVDF, polyacrylonitrile, polyethylene oxide, polyvinyl chloride, polyacrylate, polyvinylidene fluoride hexafluoropropylene, and the like, can be used.

As the non-aqueous solvent, a well-known non-aqueous solvent can be used. The kind of this non-aqueous solvent is not particularly limited. For example, cyclic carbonate ester, chain carbonate ester, cyclic carboxylate ester, and the like, can be used. An example of cyclic carbonate ester may include propylene carbonate (PC), ethylene carbonate (EC), and the like. An example of chain carbonate ester may include diethyl carbonate (DEC), ethyl methyl carbonate (EMC), dimethyl carbonate (DMC), and the like. An example of cyclic carboxylate ester may include γ-butyrolactone (GBL), γ-valerolactone (GVL), and the like. The non-aqueous solvent may be used singly or may be in a combination of two or more thereof.

An example of the solute to be solved in a non-aqueous solvent may include LiClO₄, LiBF₄, LiPF₆, LiAlCl₄, LiSbF₆, LiSCN, LiCF₃SO₃, LiCF₃CO₂, LiAsF₆, lower aliphatic lithium carboxylate, LiCl, LiBr, LiI, chloroborane lithium, borates, imide salts, and the like. An example of borates may include lithium bis(1,2-benzenedioleate(2-)-O,O′) borate, lithium bis(2,3-naphthalenedioleate(2-)-O,O′) borate, lithium bis(2,2′-biphenyldioleate(2-)-O,O′) borate, lithium bis(5-fluoro-2-oleate-1-benzenesulfonate-O,O′) borate, and the like. An example of imide salts may include lithium bistrifluoromethanesulfonate imide ((CF₃SO₂)₂NLi), lithium trifluoromethanesulfonate nonafluorobutanesulfonate imide (LiN(CF₃SO₂)(C₄F₉SO₂)), lithium bispentafluoroethanesulfonate imide ((C₂F₅SO₂)₂NLi), and the like. The solute may be used singly or may be used in a combination of two or more thereof.

Furthermore, the non-aqueous electrolyte may include a material as an additive, which is decomposed on negative electrode 6 and is capable of forming a coating film having high conductivity of lithium ions and increasing the charge and discharge efficiency. An example of the additive having such a function may include vinylene carbonate, 4-methyl vinylene carbonate, 4,5-dimethyl vinylene carbonate, 4-ethyl vinylene carbonate, 4,5-diethyl vinylene carbonate, 4-propyl vinylene carbonate, 4,5-dipropyl vinylene carbonate, 4-phenyl vinylene carbonate, 4,5-diphenyl vinylene carbonate, vinyl ethylene carbonate, divinyl ethylene carbonate, and the like. These may be used singly or in a combination of two or more thereof. Among them, at least one selected from the group consisting of vinylene carbonate, vinyl ethylene carbonate, and divinyl ethylene carbonate is preferable. Note here that a part of hydrogen atoms of the above-mentioned compounds may be substituted by a fluorine atom. It is preferable that the amount of the additive to be solved in the non-aqueous electrolyte solution is 0.1 wt. % or more and 15 wt. % or less.

Furthermore, the non-aqueous electrolyte may contain a well-known benzene derivative that is decomposed at the time of overcharging and forms a coating film on positive electrode 5 so as to inactivate a battery. As such a benzene derivative, one having a phenyl group and a cyclic compound group neighboring to this phenyl group is preferred. As the cyclic compound group, a phenyl group, a cyclic ether group, a cyclic ester group, a cycloalkyl group, a phenoxy group, and the like, are preferred. A specific example of the benzene derivative may include cyclohexylbenzene, biphenyl, diphenyl ether, and the like. These may be used singly or may be in a combination of two or more thereof. However, it is preferable that the content of the benzene derivative is 10 vol. % or less with respect to the entire non-aqueous solvent.

Next, negative electrode 6 and a method for manufacturing the same are described. Negative electrode 6 includes a current collector, and an active material layer formed on the surface of the current collector and being capable of electrochemically absorbing and releasing lithium ions. For the active material layer, in addition to a carbon material, a material such as Si and Sn capable of absorbing and releasing a large quantity of lithium ions can be used. The ratio A/B of volume A in a charged state to volume B of the material in a discharged state in this kind of active material is 1.2 or more. The volumes are determined by, for example, measuring the thickness before and after charging. Such a material can exert the effect of the present invention regardless of whether the material is any form of an elemental substance, an alloy, a compound, a solid solution and a composite material such as a silicon-containing material or a tin-containing material. That is to say, an example of the silicon-containing material may include Si and SiOₓ (0≦x≦2) or an alloy, a compound or a solid solution thereof obtained by substituting a part of Si by at least one element selected from B, Mg, Ni, Ti, Mo, Co, Ca, Cr, Cu, Fe, Mn, Nb, Ta, V, W, Zn, C, N, and Sn. As the tin-containing material, Ni₂Sn₄, Mg₂Sn and SnOₓ (0≦x≦2), SnO₂, SnSiO₃, LiSnO, and the like, can be used.

An example of formation of an active material layer from plural kinds of materials may include a compound containing Si, oxygen and nitrogen or a composite of plurality of compounds containing Si and oxygen with different constituting ratios of Si and oxygen. Among them, SiOₓ (0.3≦x≦1.3) is preferred because the discharge capacity density is large and the expansion coefficient at the time of charging is smaller than that of Si elemental substance.

Furthermore, these materials may be formed into an active material layer by mixing an active material powder with a binder, a conductive agent, and the like, and then coating, drying and roll-pressing the mixture on the current collector. Alternatively, a thin film composed of an active material may be directly formed on the current collector by a technique such as a vacuum vapor deposition method, a sputtering method, and a CVD method. In particular, the latter technique gives negative electrode 6 an excellent property of improving the charge and discharge cycle characteristics because a current collection can be always secured when a material having a large capacity and having large expansion and contraction is used for an active material.

For the current collector, a metal foil such as stainless steel, nickel, copper, titanium, and the like, a thin film of carbon or conductive resin, and the like, can be used. In addition, a current collector that may be preliminary subjected to a surface treatment with carbon, nickel, titanium, and the like, may be used. Similar to the case of the positive electrode, the thickness of the current collector is not particularly limited, but it is preferably in the range of 1 to 500 μm and more preferably in the range of 5 to 20 μm. When the thickness of the current collector falls within the above-mentioned range, the weight of the electrode can be reduced while the electrode keeps an adequate strength.

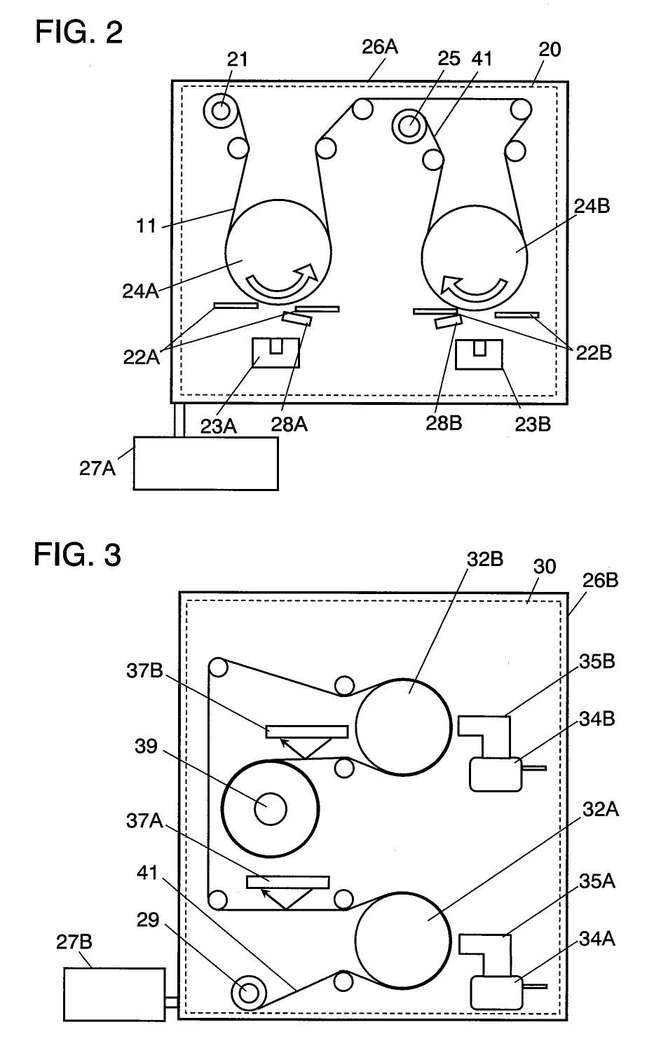

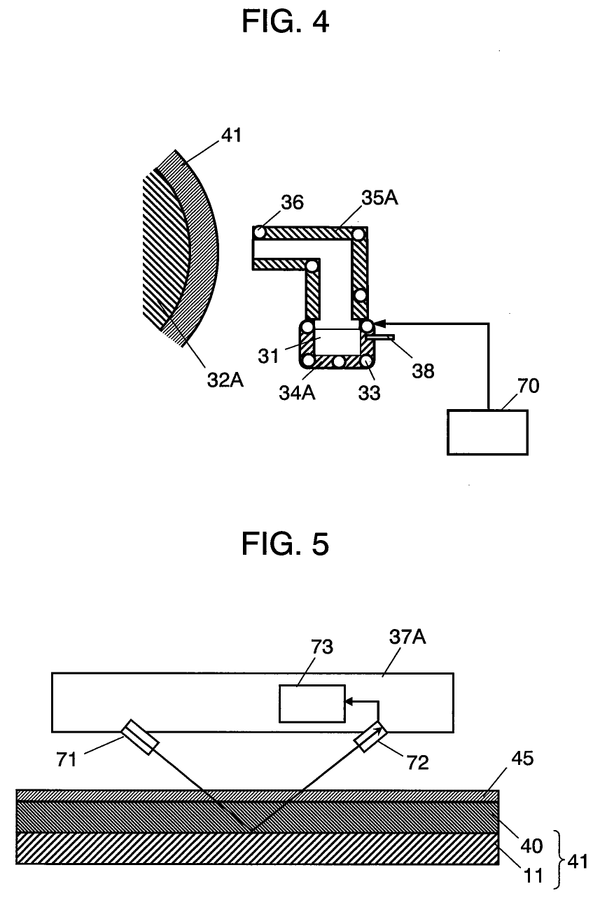

Next, with reference to FIGS. 2 to 6, a procedure for producing negative electrode 6, which uses an electrolytic copper foil as a current collector and an active material layer that contains silicon oxide (SiOₓ (0≦x≦2)), an entire manufacturing apparatus and a lithium providing section that is a lithiation treatment apparatus are described. FIG. 2 is a schematic configuration view showing an active material layer-formation section for producing a negative electrode precursor in an apparatus for manufacturing a negative electrode for a non-aqueous electrolyte secondary battery in accordance with an embodiment of the present invention. FIG. 3 is a schematic configuration view showing the lithium providing section. FIG. 4 is an enlarged sectional view showing a principal part of the lithium providing section shown in FIG. 3. This manufacturing apparatus has active material layer-formation section 20 shown in FIG. 2 and lithium providing section 30 shown in FIG. 3. Active material layer-formation section 20 is accommodated in chamber 26A and lithium providing section 30 is accommodated in chamber 26B, respectively. The pressure inside chamber 26A is reduced by vacuum pump 27A and the pressure inside chamber 26B is reduced by vacuum pump 27B.

As shown in FIG. 2, active material layer-formation section 20 includes feeding roll 21, film-formation rolls 24A and 24B, masks 22A and 22B, vapor deposition units 23A and 23B, nozzles 28A and 28B, and winding-up roll 25. Current collector 11 is forwarded from feeding roll 21 to winding-up roll 25 by way of film-formation rolls 24A and 24B. Each of vapor deposition units 23A and 23B has a vapor deposition source, a crucible and an electron beam generator as one unit. Firstly, procedure for forming an active material layer of negative electrode 6 on current collector 11 by using this apparatus is described.

As current collector 11, for example, an electrolytic copper foil having a thickness of 30 μm is used. The inside of chamber 26A is an inactive atmosphere that is approximate to a vacuum state, for example, an atmosphere of an argon gas with a pressure of about 10⁻³ Pa. At the time of vapor deposition, an electron beam generated by the electron beam generator is polarized by a polarization yoke, and the vapor deposition source is irradiated with the polarized electron beam. For the vapor deposition source, for example, a scrap material of Si (scrap silicon: purity of 99.999%) generated when semiconductor wafer is formed is used. On the other hand, oxygen with high purity (for example, 99.7%) is introduced from nozzle 28A disposed in the vicinity of film-formation roll 24A into chamber 26A. In this way, Si vapor generated from vapor deposition unit 23A and oxygen introduced from nozzle 28A are reacted with each other, so that SiOₓ is deposited on current collector 11 and an active material layer is formed. In this way, vapor deposition unit 23A, nozzle 28A, film-formation roll 24A form an active material layer made of SiOₓ on the surface of current collector 11 through a gas phase method by using Si in an atmosphere that includes oxygen.

The opening of mask 22A allows Si vapor to be incident to the surface of current collector 11 as vertically as possible. Furthermore, by opening and closing mask 22A, a portion in which an active material layer is not formed and current collector 11 is exposed, is formed.

Thereafter, current collector 11 is forwarded to film-formation roll 24B, and Si vapor is generated from vapor deposition unit 23B while oxygen is supplied into chamber 26B from nozzle 28B. Thus, a active material layer is formed also on another surface. Negative electrode precursor 41, in which an active material layer made of SiOₓ is formed on both surfaces of current collector 11 by this method, is wound up by winding-up roll 25. Negative electrode precursor 41 thus wound-up is taken out from chamber 26A after the inside chamber 26A is returned to atmospheric pressure by introducing argon or dry air into chamber 26A, and then set on feeding roll 29 of lithium providing section 30. Note here that when Si is used as negative electrode active material, oxygen may not be introduced from nozzles 28A and 28B. Alternatively, in FIG. 2, nozzles 28A and 28B may not be provided.

Next, a procedure for providing lithium to an active material layer of negative electrode precursor 41 is described with reference to FIGS. 3 and 4. Lithium providing section 30 includes feeding roll 29, copper crucibles 34A and 34B into which rod heater 33 as a heater is incorporated, lithium vapor deposition nozzles 35A and 35B, cooling CANs 32A and 32B and winding-up roll 39. Since the configurations of copper crucible 34B, lithium vapor deposition nozzle 35B and cooling CAN 32B are the same as those of copper crucible 34A, lithium vapor deposition nozzle 35A and cooling CAN 32A, respectively, the description thereof is omitted.

Negative electrode precursor 41 set on feeding roll 29 is disposed so that it is forwarded to winding-up roll 39 via cooling CANs 32A and 32B that are cooled to, for example, 20° C. Then, a lithium alloy containing an element is placed in copper crucible 34A into which rod heater 33 is incorporated. The element is other than a constituting material of negative electrode 6 and its atomic weight is larger than that of lithium. Alternatively, such an element and lithium may be placed at a predetermined weight ratio. In this way, when the vacuum evaporation method is used, lithium providing section 30 heats an alloy prepared by preliminarily mixing lithium with the element other than a constituting material of an electrode at specified ratios, or adds the element to lithium and then heats it. By using these techniques, the element can be contained in the lithium to be provided constantly.

Then, lithium vapor deposition nozzle 35A into which rod heater 36 is incorporated is assembled into copper crucible 34A. The pressure inside chamber 26B is reduced to, for example, 3×10⁻³ Pa by vacuum pump 27B. That is to say, the pressure of the atmosphere enclosing negative electrode precursor 41 and a lithium alloy or a metallic mixture containing lithium as a vapor supplying source is reduced. In order to generate a lithium vapor and a vapor of the above-mentioned element, heat controller 70 applies electricity to rod heater 33 so as to heat vapor supplying source 31 in copper crucible 34A. Furthermore, it is preferable that electricity is also applied to rod heater 36 in order to avoid cooling of vapor inside lithium vapor deposition nozzle 35A and depositing of lithium. The temperatures of copper crucible 34A and lithium vapor deposition nozzle 35A are controlled to be, for example, 580° C. by monitoring with thermocouple 38. Herein, lithium vapor deposition nozzle 35A limits the movement route of a lithium vapor. The lithium vapor is supplied to negative electrode precursor 41 via lithium vapor deposition nozzle 35A, so that lithium is provided to the active material layer of negative electrode precursor 41. By limiting the movement route of the lithium vapor in this way, the vapor can be supplied to the active material layer efficiently.

Negative electrode precursor 41 in which lithium and the above-mentioned element are provided to one of the active material layers is forwarded to cooling CAN 32B, and lithium is provided to the active material layer on the opposite surface from copper crucible 34B and lithium vapor deposition nozzle 35B. In this way, negative electrode precursor 41, in which lithium and the above-mentioned element are provided to the active material layers on both surfaces, is wound up by winding-up roll 39. Thereafter, argon or dry air is introduced into chamber 26B so as to return the pressure to atmospheric pressure, negative electrode precursor 41 is cut into a predetermined dimension, and negative electrode lead 6A is connected thereto. Thus, negative electrode 6 is produced.

Note here that chamber 26A and chamber 26B may be linked to each other with a path and active material layer-formation section 20 and lithium providing section 30 may be accommodated in one integral chamber. In this case, the pressure inside chamber 26A and 26B and the path is reduced by vacuum pump 27A. Winding-up roll 25 and feeding roll 29 are not provided, and negative electrode precursor 41 produced by active material layer-formation section 20 is forwarded to lithium providing section 30 under reduced pressure.

Next, a method for estimating the amount of lithium to be provided per unit area of the active material layer in negative electrode precursor 41 is described with reference to FIGS. 3 and 5. FIG. 5 is a view showing a configuration of the periphery of a fluorescent X-ray analyzer (XRF) that is a measurement section incorporated in the lithium providing section shown in FIG. 3. As shown in FIG. 3, measurement sections 37A and 37B are disposed behind cooling CANs 32A and 32B, respectively. Since the configuration of measurement section 37B is the same as that of measurement section 37A, the function and effect of measurement section 37A are described only as an example hereinafter.

As shown in FIG. 5, measurement section 37A includes X-ray generator 71, determining section 72 and calculation section 73. X-ray generator 71A irradiates active material layer 40 with X-ray. Determining section 72 receives a fluorescent X-ray generated from active material layer 40. Calculation section 73 calculates the intensity of Ka ray of element 45 provided to active material layer 40 together with lithium among fluorescent X-ray which determining section 72 receives.

The atomic weight of element 45 is larger than that of lithium. Therefore, the speed of element 45 to be taken into by active material layer 40 is smaller than that of lithium. Alternatively, element 45 is not taken into by active material layer 40 but left on the surface of active material layer 40 as shown in FIG. 5. Then, by calculating the intensity of Kα ray of element 45, the amount of element 45 provided per unit area of negative electrode precursor 41 can be calculated. Thus, by preliminarily confirming the ratio of lithium and element 45 contained in the vapor released from lithium vapor deposition nozzle 35A, the amount of lithium provided per unit area of negative electrode precursor 41 can be estimated indirectly. In this way, it is possible to estimate the amount of lithium provided per unit area of negative electrode precursor 41. Thus, it is possible to manage the amount of provided lithium. Therefore, negative electrode precursor 41 can be lithiated with an appropriate amount of lithium, and a non-aqueous electrolyte secondary battery having a stable property can be manufactured.

Furthermore, this estimated amount or the amount of element 45 provided per unit area is fed back to heat controller 70 so as to control the heat amount of rod heater 33. Thus, the generation amount of vapor is controlled, and thereby the amount of lithium provided per unit area of negative electrode precursor 41 can be controlled. In other words, a necessary amount of lithium is provided and the amount can be made to be uniform.

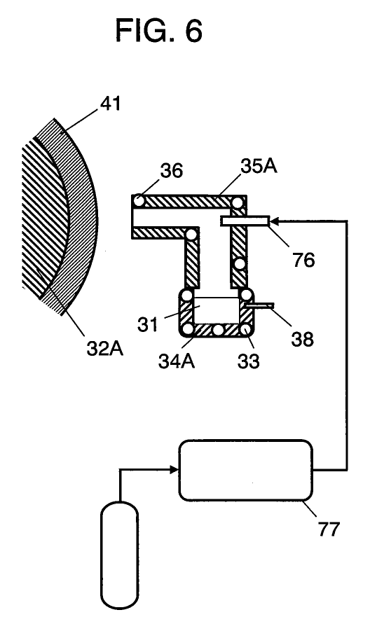

Alternatively, the transportation amount of vapor may be limited by a configuration shown in FIG. 6. FIG. 6 is an enlarged view of a principal part showing another configuration of the lithium providing section shown in FIG. 3. In this configuration, nozzle 76 and gas flow controller 77 are provided. Nozzle 76 opens inside lithium vapor deposition nozzle 35A and allows argon to flow into the movement route of vapor.

By the time the vapor starts to be generated from copper crucible 34A, nozzle 76 starts to allow argon to flow into the movement route of lithium vapor. The flow rate at this time is set to, for example, 100 sccm. Thus, when argon is allowed to flow in lithium vapor deposition nozzle 35A that is a movement route of lithium vapor, the transportation amount of the lithium vapor can be limited as compared with the case where the gas is not allowed to flow. Then, the determination results of the amount of element 45 by measurement section 37A or the estimation result of the amount of provided lithium is fed back to gas flow controller 77 so as to control the flow rate of argon, and thereby the amount of lithium provided per unit area of negative electrode precursor 41 can be controlled. Instead of argon, other noble gas, hydrogen or a mixture gas thereof may be allowed to flow from nozzle 76.

Note here that in FIG. 6, nozzle 76 is set so that argon is allowed to flow in the direction in parallel to the direction in which a lithium vapor moves in lithium vapor deposition nozzle 35A. However, it may be set so that it allows argon to flow toward the heated vapor supplying source 31.

Furthermore, the rotation speeds of feeding roll 29 and winding-up roll 39 may be controlled, thereby controlling the movement speed of negative electrode precursor 41. That it to say, such a rotation speed controller may be provided. This method can also control the amount of lithium provided per unit area of negative electrode precursor 41. However, this can be applied only when the amounts of vapors released from vapor deposition nozzles 35A and 35B are the same in the case where lithium is provided continuously to both surfaces of negative electrode precursor 41 as shown in FIG. 3. Therefore, when this method is applied, preferably, after lithium is provided to one surface of negative electrode precursor 41, negative electrode precursor 41 is wound up once.

As mentioned above, in a manufacturing apparatus for a negative electrode of a non-aqueous electrolyte secondary battery in accordance with the embodiment, the amount of lithium to be provided per unit area can be kept substantially constant. Note here that, for example, the amount of lithium provided per unit area may be shown on a display such as a liquid crystal panel, or alarm may be used to notify the case where the amount is beyond a predetermined range. Thus, an operator can judge whether or not the amount of provided lithium in the manufacturing lot is in an appropriate range.

It is preferable that potassium, calcium, or a mixture or an alloy thereof is used as element 45. Such elements are easily vaporized together with lithium. Furthermore, when silicon or the compound thereof is used as a material for the electrode, since such elements are heavier than silicon, they are easily detected by XRF. Furthermore, sodium and magnesium may be used as element 45. Sodium and magnesium are also vaporized easily together with lithium. Furthermore, it is also preferable that element 45 is at least one selected from aluminum, tin, zinc, lead, bismuth and phosphorus. Since these elements have a relatively low melting point and high vapor pressure, they are easily vaporized together with lithium. Moreover, since they are heavier elements than lithium, they are detected more easily. It is preferable to use at least one selected from these elements.

Furthermore, in this embodiment, the pressure of an atmosphere enclosing negative electrode precursor 41 and vapor supplying source 31 is reduced by vacuum pump 27B, and vapor supplying source 31 is heated by rod heater 33. For providing lithium, such a vacuum evaporation method is an effective method.

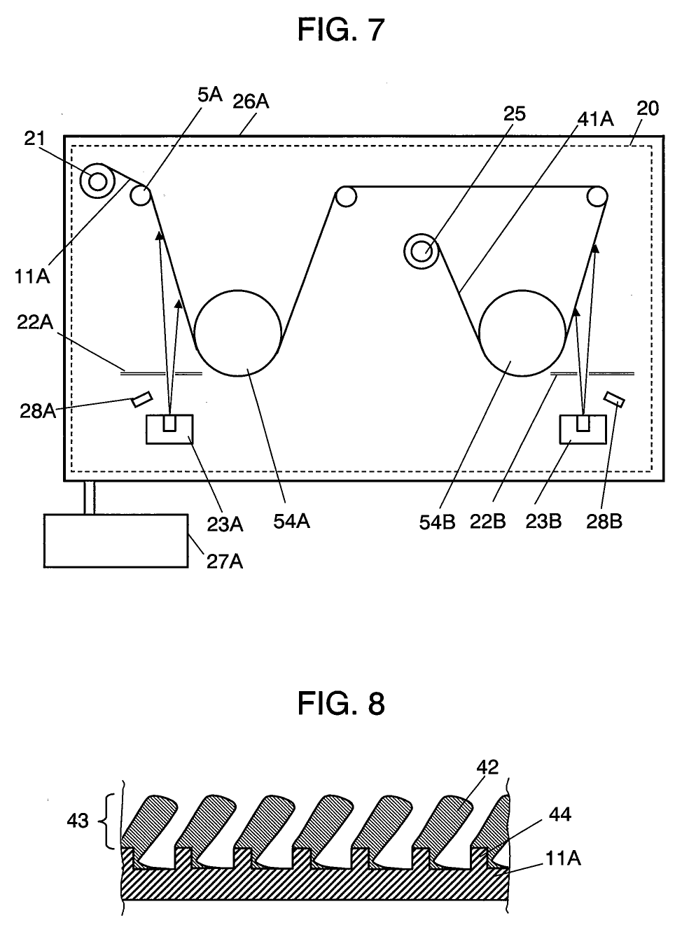

Next, an active material layer-formation section for forming an active material layer of a more preferable embodiment is described with reference to FIG. 7. FIG. 7 is a schematic configuration view showing another active material layer-formation section in a manufacturing apparatus for a negative electrode for a non-aqueous electrolyte secondary battery in accordance with an embodiment of the present invention, which is used for producing an active material having an inclined columnar structure. FIG. 8 is a sectional view showing a negative electrode for a non-aqueous electrolyte secondary battery produced by using the active material layer-formation section shown in FIG. 7.

Active material layer-formation section 20 shown in FIG. 7 includes feeding roll 21, fulcrum rolls 54A and 54B, masks 22A and 22B, vapor deposition units 23A and 23B, nozzles 28A and 28B and winding-up roll 25. Since the configuration except for fulcrum rolls 54A and 54B are the same as those in FIG. 2, the description thereof is omitted. In this configuration, current collector 11A is forwarded from feeding roll 21 to winding-up roll 25 via fulcrum rolls 54A and 54B. During the time, active material layer 43 of SiOₓ is formed from Si vapor from vapor deposition units 23A and 23B and oxygen from nozzles 28A and 28B on both surfaces of current collector 11A. These rolls and vapor deposition units 23A and 23B are provided in chamber 26A. The inside chamber 26A is reduced by vacuum pump 27A.

As shown in FIG. 8, current collector 11A has a large number of protrusions 44 on the surface thereof. For example, a 30 μm-thick electrolytic copper foil is used as current collector 11A. In the foil, concavity and convexity having an average surface roughness of 2.0 μm are formed by electrolytic plating. Protrusions 44 are provided on both surfaces of current collector 11A, but only one surface is shown in FIG. 8 for simplification.

The inside chamber 26A is made to be an atmosphere of a low-pressure inactive gas, for example, an atmosphere of an argon gas with a pressure of 3.5 Pa. At the time of vapor deposition, the vapor deposition source is irradiated with an electron beam generated by the electron beam generator and polarized by a polarization yoke. The shapes of the openings of masks 22A and 22B are adjusted so that Si vapor generated from vapor deposition units 23A and 23B is not vertically supplied to the surface of current collector 11A.

In this way, current collector 11A is forwarded from feeding roll 21 to winding-up roll 25 while Si vapor is supplied to the surface of current collector 11A. Then, when oxygen is introduced into chamber 26A from nozzle 28A that is placed at a predetermined angle with respect to the incident direction of Si vapor, active material lumps 42 of SiOₓ are provided in a way in which they grow from protrusion 44 as starting points. At this time, when the predetermined angle is set to 65° for example, oxygen gas with a purity of 99.7% is introduced from nozzle 28A into chamber 26A, and active material lumps 42 are formed at the formation speed of about 20 nm/sec, 21 μm-thick columnar active material lumps 42 of SiO_{0.4} are formed on protrusion 44 of current collector 11A. After active material lumps 42 are formed on one surface before fulcrum roll 54A, current collector 11A is forwarded to fulcrum roll 54B, and active material lumps 42 can be formed on the other surface by the same method. In this way, negative electrode 41A in which active material layer 43 is formed on each surface of current collector 11A is produced.

Note here that heat resistant tapes are attached in equal intervals on both surfaces of current collector 11A in advance and these tapes are detached after active material lumps 42 are formed. Thereby, exposed portions to which negative electrode lead 6A is welded can be formed. Thereafter, lithium is provided to active material layer 43 on both surfaces by using lithium providing section 30 shown in FIG. 4.

In this way, it is preferable that active material layer 43 is formed as a plurality of columnar active material lumps 42 on current collector 11A. In addition to the above-mentioned method, by the methods disclosed in Japanese Patent Application Unexamined Publication Nos. 2003-17040 and 2002-279974, negative electrode 6 having current collector 11A and a plurality of columnar active material lumps provided on the surface of current collector 11A may be produced. When the active material has a columnar structure, since expansion of the active material can be absorbed in space between columns, it is effective against the expansion and contract of the active material as compared with a smooth film structure.

Furthermore, it is further preferable that active material lumps 42 are formed in a way in which they are inclined with respect to the thickness direction of current collector 11A. By inclining active material lumps 42 with respect to the thickness direction of current collector 11A in this way, the expansion and contraction of the active material can be absorbed in space effectively and the charge and discharge cycle characteristics of negative electrode 6 can be improved. The reason therefor is not clear, but one of the reasons is thought to be as follows. Elements having a lithium ion absorbing property is expanded and contracted when it absorbs and releases lithium ions. Stress accompanied by the expansion and contraction is dispersed in the parallel direction and the vertical direction to the surface of current collector 11A where active material lumps 42 are made. Therefore, the generation of wrinkle of current collector 11A and exfoliation of active material lumps 42 are suppressed, so that the charge and discharge cycle characteristics are thought to be improved. Furthermore, since this is a shape capable of forming a film at a high speed, this is preferable from the viewpoint of mass productivity.

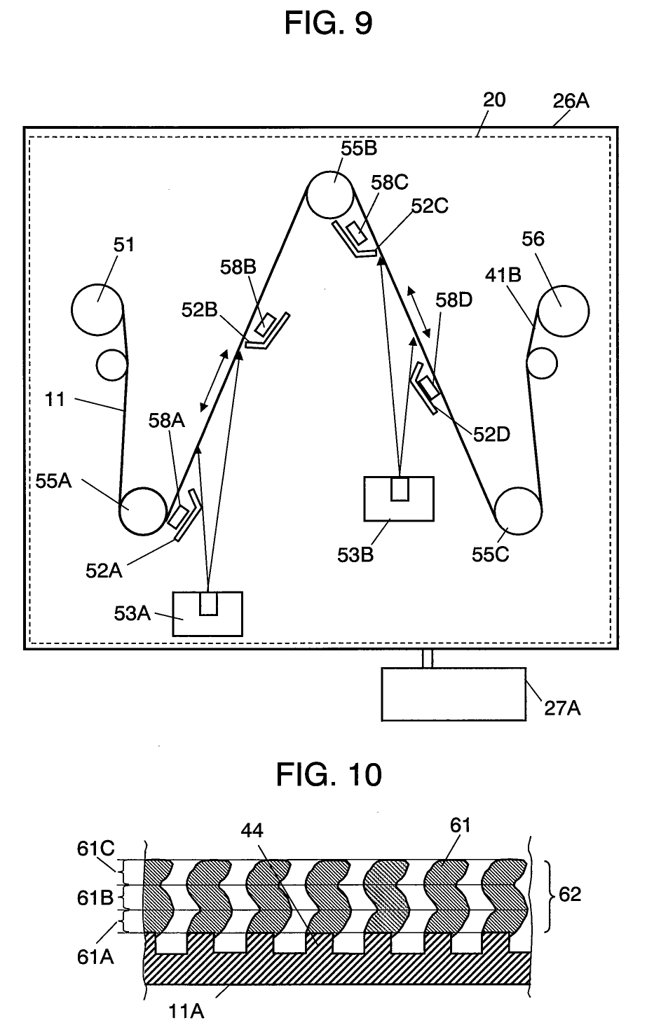

Next, an active material layer-formation section for forming an active material layer of a further preferable embodiment is described with reference to FIG. 9. FIG. 9 is a schematic configuration view showing another active material layer-formation section in an apparatus for manufacturing a negative electrode of a non-aqueous electrolyte secondary battery in accordance with an embodiment of the present invention. FIG. 10 is a sectional view showing a negative electrode for a non-aqueous electrolyte secondary battery manufactured by the active material layer-formation section shown in FIG. 9. Note here that FIG. 10 shows only one surface of negative electrode 6 for simplification. Current collector 11A shown in these drawings is the same as current collector 11A shown in FIGS. 7 and 8.

Active material layer-formation section 20 shown in FIG. 9 includes feeding roll 51, fulcrum rolls 55A, 55B and 55C, masks 52A, 52B, 52C and 52D, vapor deposition units 53A and 53B, nozzles 58A, 58B, 58C and 58D, and winding-up roll 56. Fulcrum roll 55A is a first fulcrum, fulcrum roll 55B is a second fulcrum, and fulcrum roll 55C is a third fulcrum. These are provided in chamber 26A. The pressure inside chamber 26A is reduced by vacuum pump 27A. Vapor deposition units 53A and 53B are the same as vapor deposition units 23A and 23B shown in FIGS. 3 and 6.

Next, as shown in FIG. 10, a procedure for forming active material layer 62 that is an active material layer of one side of a negative electrode on current collector 11A is described. The inside chamber 26A is an inactive atmosphere that is approximate to a vacuum state, for example, an atmosphere of an argon gas with a pressure of about 3.5 Pa. At the time of vapor deposition, the vapor deposition source is irradiated with an electron beam generated by an electron beam generator and polarized by a polarization yoke. For the vapor deposition source, for example, a Si scrap material is used. Vapor deposition unit 53A is disposed on a position between fulcrum roll 55A and fulcrum roll 55B so that Si vapor is obliquely supplied to current collector 11A. Thus, Si vapor generated from vapor deposition unit 53A is not supplied vertically to the surface of current collector 11A. Similarly, vapor deposition unit 53B is disposed on a position between fulcrum roll 55B and fulcrum roll 55C so that Si vapor is obliquely supplied to current collector 11A.

Masks 52A, 52B, 52C and 52D cover nozzles 58A, 58B, 58C and 58D, respectively. In this configuration, current collector 11A is forwarded from feeding roll 51 while Si vapor is supplied to the surface of current collector 11A from vapor deposition unit 53A. At this time, oxygen with high purity is introduced to current collector 11A from nozzles 58A and 58B. Then, the Si vapor generated from vapor deposition unit 53A and the introduced oxygen are reacted with each other and first columnar bodies 61A of SiOₓ are generated on current collector 11A in a way in which they grow from protrusions 44 as starting points.

Next, current collector 11A on which first columnar bodies 61A are formed moves toward a position to which Si vapor is supplied from vapor deposition unit 53B. At this time, when oxygen with high purity is introduced from nozzles 58C and 58D to current collector 11A, Si vapor generated from vapor deposition unit 53B and the introduced oxygen are reacted with each other, and second columnar bodies 61B of SiOₓ are generated in a way in which they grow from first columnar bodies 61A as starting points. At this time, as shown in FIG. 10, second columnar bodies 61B grow in the direction opposite to that of first columnar bodies 61A because of the position of vapor deposition unit 53B with respect to current collector 11A.

That is to say, vapor deposition unit 53A, nozzles 58A and 58B, fulcrum rolls 55A and 55B constitutes a first formation section for forming first columnar bodies 61A of SiOₓ that grow obliquely from protrusions 44 on the surface of current collector 11A having a plurality of protrusions 44 on at least one surface thereof. On the other hand, vapor deposition unit 53B, nozzles 58C and 58D, fulcrum rolls 55B and 55C constitute a second formation section for forming second columnar bodies 61B of SiOₓ that obliquely grow from first columnar bodies 61A to increase the thickness of active material layer 62.

When the rotation directions of feeding roll 51 and winding-up roll 56 are reversed from this state, Si vapor generated from vapor deposition unit 53A and the introduced oxygen are reacted with each other and third columnar bodies 61C of SiOₓ are generated in a way in which they grow from second columnar bodies 61B as starting points. Also in this case, as shown in FIG. 10, third columnar bodies 61C grow in the opposite direction to second columnar bodies 61B. In those processes, it is possible to form active material layer 62 composed of active material lumps 61 each having a columnar structure with bending points. Furthermore, when the rotation directions of feeding roll 51 and winding-up roll 56 are reversed, fourth columnar bodies can be produced on third columnar bodies 61C. That is to say, the number of bending points can be controlled freely.

As described above, active material layer 62 composed of active material lumps 61 each having a columnar structure with bending points is formed on negative electrode precursor 41B. Then, lithium is provided by lithium providing section 30 shown in FIG. 3, to active material layer 62 of negative electrode precursor 41B prepared by active material layer-formation section 20 shown in FIG. 9. At this time, a lithium providing section having a configuration that does not use cooling CAN 32B, copper crucible 34B, and lithium vapor deposition nozzle 35B in lithium providing section 30 may be used.

In this way, negative electrode precursor 41B, in which lithium is provided to active material layer 62 formed on one surface of current collector 11A, is wound up by winding-up roll 39. Thereafter, by introducing argon or dry air into chamber 26B so as to return the pressure to atmospheric pressure. Then, if necessary, in order to form active material layer 62 and to provide lithium on the other surface of current collector 11A, current collector 11A is set to winding-up roll 51 again.

In negative electrode 6 in which active material layer 62 is thus composed of active material lumps 61 each having a columnar structure with bending points, even if active material lump 61 expands at the time of charging, active material lumps 61 are less interfered three-dimensionally with each other as compared with active material lumps 42 shown in FIG. 8. Therefore, from the viewpoint of the charge and discharge cycle characteristics, the negative electrode having a structure shown in FIG. 10 is more preferable than the negative electrode having a structure shown in FIG. 8.

In the above-mentioned embodiments, a cylindrical battery is used as an example. However, the same effect can be obtained even when, for example, it is employed in a prismatic battery. Furthermore, an active material layer is formed on only one surface of current collectors 11 and 11A and a coin type battery may be produced. Furthermore, in the above-mentioned embodiments, a non-aqueous electrolyte secondary battery is described as an example, but the present invention can be applied to an electrochemical element such as a capacitor as long as it uses a lithium ion as a electric charge carrier and at least one of the electrodes has an irreversible capacity.

As mentioned above, an electrochemical element using an electrode treated by a lithiation treatment in the manufacturing method of the present invention, has a large capacity and a long lifetime. Therefore, a non-aqueous electrolyte secondary battery that is one kind of the electrochemical elements is useful as a power source of electronic equipment such as a notebook-sized personal computer, a portable telephone and a digital still camera, and furthermore, an electric power storage and a power source for an electric vehicle both requiring high power. In manufacturing the above-mentioned electrochemical elements, the present invention provides a very important and effective means because it can manage the compensation amount of irreversible capacity.

What is claimed is:

1. A method for manufacturing an electrode of an electrochemical element, the electrode being capable of electrochemically absorbing and releasing a lithium ion, the method comprising:
forming an active material layer on a current collector so as to produce an electrode precursor; and
providing lithium and an element to the electrode precursor by using a lithium vapor and a vapor of the element, the element having a larger atomic weight than that of lithium and being other than a constituting material of the electrode precursor.

2. The method for manufacturing an electrode of an electrochemical element according to claim 1, wherein an amount of lithium provided per unit area in the electrode precursor is estimated by determining an amount of the element per unit area in the electrode precursor.

3. The method for manufacturing an electrode of an electrochemical element according to claim 2, wherein one of a generation amount of the lithium vapor, a transportation amount of the lithium vapor, and a moving speed of the electrode precursor is controlled based on one of the determined amount of the element per unit area in the electrode precursor and the estimated amount of lithium provided per unit area in the electrode precursor.

4. The method for manufacturing an electrode of an electrochemical element according to claim 1, wherein the element includes at least one selected from potassium, calcium, sodium, magnesium, aluminum, tin, zinc, lead, bismuth and phosphorus.

5. The method for manufacturing an electrode of an electrochemical element according to claim 1, wherein a pressure of an atmosphere enclosing the electrode precursor and the element and lithium that are a vapor supplying source is reduced, and the vapor supplying source is heated.

6. The method for manufacturing an electrode of an electrochemical element according to claim 5, wherein an alloy in which a specified amount of the element is preliminarily mixed with lithium is heated, or a specified amount of the element is added to lithium and they are heated.

7. An electrochemical element comprising:
a first electrode manufactured by a method for manufacturing an electrode of an electrochemical element according to claim 1;
a second electrode capable of electrochemically absorbing and releasing a lithium ion; and
an electrolyte interposed between the first electrode and the second electrode.

8. A lithiation treatment method for an electrode of an electrochemical element, the electrode being capable of electrochemically absorbing and releasing a lithium ion, the method comprising:
providing lithium and an element to the electrode by using a lithium vapor and a vapor of the element, the element having a larger atomic weight than that of lithium and being other than a constituting material of the electrode.

9. The lithiation treatment method for an electrode of an electrochemical element according to claim 8, wherein an amount of lithium provided per unit area in the electrode is estimated by determining an amount of the element per unit area in the electrode.

10. The lithiation treatment method for an electrode of an electrochemical element according to claim 9, wherein one of a generation amount of the lithium vapor, a transportation amount of the lithium vapor, and a moving speed of the electrode is controlled based on one of the determined amount of the element per unit area in the electrode and the estimated amount of lithium provided per unit area in the electrode.

11. The lithiation treatment method for an electrode of an electrochemical element according to claim 8, wherein the element includes at least one selected from potassium, calcium, sodium, magnesium, aluminum, tin, zinc, lead, bismuth and phosphorus.

12. The lithiation treatment method for an electrode of an electrochemical element according to claim 8, wherein a pressure of an atmosphere enclosing the electrode and the element and lithium that are a vapor supplying source is reduced, and the lithium of the vapor supplying source is heated.

13. The lithiation treatment method for an electrode of an electrochemical element according to claim 12, wherein an alloy in which a specified amount of the element is preliminarily mixed with lithium is heated, or a specified amount of the element is added to lithium and they are heated.

14. An electrochemical element comprising:
a first electrode capable of electrochemically absorbing and releasing a lithium ion, the first electrode being treated by a lithiation treatment method for an electrode of an electrochemical element according to claim 8;
a second electrode capable of electrochemically absorbing and releasing a lithium ion; and
an electrolyte interposed between the first electrode and the second electrode.

15. An apparatus for lithiation treatment of an electrode of an electrochemical element, the electrode being capable of electrochemically absorbing and releasing a lithium ion, the apparatus comprising:
a lithium providing section configured to provide lithium and an element to the electrode by using a lithium vapor and a vapor of the element, the element having a larger atomic weight than that of lithium and being other than a constituting material of the electrode; and
a chamber accommodating the lithium providing section.

16. The apparatus for lithiation treatment of an electrode of an electrochemical element according to claim 15, further comprising:
a measurement section configured to estimate an amount of lithium provided per unit area in the electrode by determining an amount of the element per unit area in the electrode.

17. The apparatus for lithiation treatment of an electrode of an electrochemical element according to claim 16, further comprising:
a controller configured to control one of a generation amount of the lithium vapor, a transportation amount of the lithium vapor, and a moving speed of the electrode based on one of the amount of the element per unit area in the electrode determined by the measurement section and the amount of lithium provided per unit area in the electrode estimated by the measurement section.

18. The apparatus for lithiation treatment of an electrode of an electrochemical element according to claim 15, wherein the lithium providing section uses at least one selected from potassium, calcium, sodium, magnesium, aluminum, tin, zinc, lead, bismuth and phosphorus as the element.

19. The apparatus for lithiation treatment of an electrode of an electrochemical element according to claim 15, further comprising:
a heater provided in the chamber to heat the element and lithium that are a supplying source for generating the lithium vapor and the vapor of the element; and
a vacuum pump configured to reduce a pressure inside the chamber.

20. The apparatus for lithiation treatment of an electrode of an electrochemical element according to claim 19, wherein the heater heats an alloy in which a specified amount of the element is preliminarily mixed with lithium, or heats after a specified amount of the element is added to lithium.

21. An apparatus for manufacturing an electrode of an electrochemical element, the electrode being capable of electrochemically absorbing and releasing a lithium ion, the apparatus comprising:
an active material layer-formation section configured to form an active material layer on a current collector so as to produce an electrode precursor;
a lithium providing section configured to provide lithium and an element to the electrode precursor by using a lithium vapor and a vapor of the element, the element having a larger atomic weight than that of lithium and being other than a constituting material of the electrode precursor; and
a chamber accommodating the lithium providing section.

22. The apparatus for manufacturing an electrode of an electrochemical element according to claim 21, further comprising:
a measurement section configured to estimate an amount of lithium provided per unit area in the electrode precursor by determining an amount of the element per unit area in the electrode precursor.

23. The apparatus for manufacturing an electrode of an electrochemical element according to claim 22, further comprising:
a controller configured to control one of a generation amount of the lithium vapor, a transportation amount of the lithium vapor, and a moving speed of the electrode precursor based on one of the amount of the element per unit area in the electrode precursor determined by the measurement section and the amount of lithium provided per unit area in the electrode precursor estimated by the measurement section.
a controller for controlling a generation amount or a transportation amount of the lithium vapor or a moving speed of the electrode based on the amount of the element per unit area in the electrode determined by the measurement section or the estimated amount of lithium provided per unit area in the electrode.

24. The apparatus for manufacturing an electrode of an electrochemical element according to claim 21, wherein the lithium providing section uses at least one selected from potassium, calcium, sodium, magnesium, aluminum, tin, zinc, lead, bismuth and phosphorus as the element.

25. The apparatus for manufacturing an electrode of an electrochemical element according to claim 21, further comprising:
a heater provided in the chamber to heat the element and lithium that are a supplying source for generating the lithium vapor and the vapor of the element; and
a vacuum pump configured to reduce a pressure inside the chamber.

26. The apparatus for manufacturing an electrode of an electrochemical element according to claim 25, wherein the heater heats an alloy in which a specified amount of the element is preliminarily mixed with lithium, or heats after a specified amount of the element is added to lithium.

27. An electrode of an electrochemical element, comprising:
an active material capable of electrochemically absorbing and releasing a lithium ion, and
at least one selected from potassium, calcium, sodium, magnesium, aluminum, tin, zinc, lead, bismuth and phosphorus,
wherein the electrode is provided with lithium.
